(19) United States
(12) Patent Application Publication
(10) Pub. No.: US 2005/0219911 A1
(43) Pub. Date: Oct. 6, 2005

(54) Non-volatile memory circuit and semiconductor device

(76) Inventors: Masashi Sakai, Chiba-shi (JP); Michiyasu Deguchi, Chiba-shi (JP)

Correspondence Address: BRUCE L. ADAMS, ESQ.;31ST FLOOR, 50 BROADWAY, NEW YORK, NY, 10004, US

(21) Appl. No.: 11/088,213

(22) Filed: Mar. 23, 2005

(30) Foreign Application Priority Data
Mar. 30, 2004 (JP) 2004-097820

(51) Int. Cl. G11C 16/06

(52) U.S. Cl. 365/185.23

(57) ABSTRACT

A trimming circuit having an EPROM is provided which enables trimming after packaging without the increase of the number of terminals. An EPROM write voltage is generated by an internal resistor. Accordingly, read/write of the EPROM can be performed without addition of voltage terminals.

### BACKGROUND OF THE INVENTION

1. Field of the Invention

The present invention relates to an electrically writable non-volatile memory circuit, and to a semiconductor device having a trimming means using the circuit.

2. Description of the Related Art

In recent years, a large quantity of power control ICs have been utilized by being incorporated into various kinds of electronic products. Setting voltages of the power control ICs are not only variously but also precisely set in accordance with the applications before packaging in manufacturing factories. Therefore, the industry of electronic equipment has a problem of stocks besides a problem of high manufacturing costs of the power control ICs.

In view of the above, there are required the power control ICs in which desired voltages can be set after packaging and which can deal with the problem of high manufacturing costs and the problem of stocks. Thus, there has been proposedapower control IC provided with an electrically writable non-volatile memory circuit.

FIG. 2 shows a conventional EPROM read/write circuit using an EPROM. The circuit is constituted by resistors 20 and 24, a PMOS transistor 21, NMOS transistors 23 and 25, and an EPROM 22. Further, the circuit includes a power source voltage terminal 1 for the normal operation and a first write voltage terminal 4 and second write voltage terminal 5 for write to the EPROM.

For the write to the EPROM 22, a voltage of 10 V is applied to the first write voltage terminal 4, a voltage of 19 V is applied to the second write voltage terminal 5, and a read command signal, which is input from a read control terminal 6, sets the NMOS transistor 25 in a non-conductive state. When the NMOS transistor 23 is made conductive by a write command signal input from a write control terminal 2, a GND potential is applied to a gate terminal of the PMOS transistor 21, whereby the PMOS transistor 21 becomes conductive. Thus, a current flows between a source and a drain of the EPROM 22, and a carrier is injected to a floating gate. Therefore, a threshold of the EPROM 22 becomes a high threshold Vth_h, which leads to a write state.

Further, in order to maintain an initial state (hereinafter, referred to as an erase state) of the EPROM 22 in which no data is written, when the NMOS transistor 23 is made non-conductive by the write command signal input from the write control terminal 2, the voltage at the first write voltage terminal 4 is applied to the gate terminal of the PMOS transistor 21. As a result, the PMOS transistor 21 is made non-conductive. Thus, the current does not flow between the source and the drain of the EPROM 22, and the carrier is not injected to the floating gate. Therefore, the threshold of the EPROM 22 remains at an initial threshold Vth_l, which leads to the erase state.

On the other hand, as to read from the EPROM 22, a voltage of 5 V is applied to the second write voltage terminal 5, the PMOS transistor 21 is set in a non-conductive state, and the NMOS transistor 25 is set in a conductive state.

When the EPROM 22 is in the write state, the threshold of the EPROM 22 is Vth_h, and the gate terminal is applied with a voltage lower than the threshold. As a result, the EPROM 22 becomes non-conductive, and thus, an output voltage terminal 3 is at a high potential.

When the EPROM 22 is in the erase state, the threshold of the EPROM 22 is Vth_l, and the gate terminal is applied with a voltage higher than the threshold. As a result, the EPROM 22 becomes conductive, and thus, the output voltage terminal 3 is at a low potential (refer to, for example, JP 2003-110029 A).

However, in the conventional EPROM read/write circuit, the number of terminals increases since the write voltage terminals are separately required. The increase of the number of terminals leads to the rise in costs of electronic products because of, for example, design change of the electronic products largely utilized in the currently available packages. Further, as a measure for preventing the increase of the number of terminals, there is a measure for obtaining a write voltage with the use of a booster circuit provided in an integrated circuit. However, this leads to the increase of a circuit scale, which invites enlargement of a chip size. This results in the increase of manufacturing costs, and cannot realize mounting in the currently available packages.

### SUMMARY OF THE INVENTION

The present invention has been made with a view to solving the above-mentioned problems, and therefore has an object to provide a non-volatile memory circuit which enables trimming after packaging without the increase of the number of terminals.

According to the present invention, in order to attain the above-mentioned object, switching of a power source voltage value is performed outside at the time of write and the time of read. In the case of performing write to an EPROM, a voltage applied to a power source voltage terminal is dropped by a resistor, and the resultant voltage is taken as a write voltage. Therefore, the read/write of the EPROM is enabled without providing a write terminal.

More specifically, an electrically writable non-volatile memory circuit, which includes a power source terminal, control terminal, control transistor, EPROM, and output terminal, is structured such that: a resistor is provided between the power source terminal and the control transistor; the control transistor is connected to the EPROM, a connecting point therebetween is connected to the output terminal; the power source terminal is connected to a gate of the EPROM; and the control terminal is connected to the control transistor.

Further, the electrically writable non-volatile memory circuit is structured such that a signal is input to the control terminal to turn the control transistor on, and a write voltage is applied to the power source terminal to perform write operation of the EPROM at the time of write, and a signal is input to the control terminal to turn the control transistor on, and a read voltage is applied to the power source terminal to output information written in the EPROM to the output terminal at the time of read.

Further, the present invention provides a semiconductor device, including a trimming means composed of an electrically writable non-volatile memory, in which plural resistors are connected one another in series in the trimming means, switching transistors are connected in parallel to both ends of each of the resistors, and each of the switching transistors is controlled by the non-volatile memory circuit.

In the electrically writable non-volatile memory circuit according to the present invention, conventional packaging itself can be used. Thus, costs can be reduced by holding down the chip size and the number of terminals. Further, the EPROM read/write circuit of the present invention is utilized in a control device of a MOS switch in the trimming circuit. Thus, an output from the trimming circuit can be set to a desired voltage even after packaging. Accordingly, the manufacturing costs can be reduced, and the problem of stocks can be solved.

### BRIEF DESCRIPTION OF THF DRAWINGS

In the accompanying drawings:

FIG. 1 is a diagram of an EPROM read/write circuit according to the present invention;

FIG. 2 is a diagram of a conventional EPROM read/write circuit;

FIG. 3 shows a sectional structure of an EPROM;

FIG. 4 is a diagram of a threshold voltage and a read voltage of the EPROM; and

FIG. 5 shows a trimming circuit including the EPROM read/write circuits according to the present invention.

### DETAILED DESCRIPTION OF THE PREFERRED EMBODIMENTS

### Embodiment 1

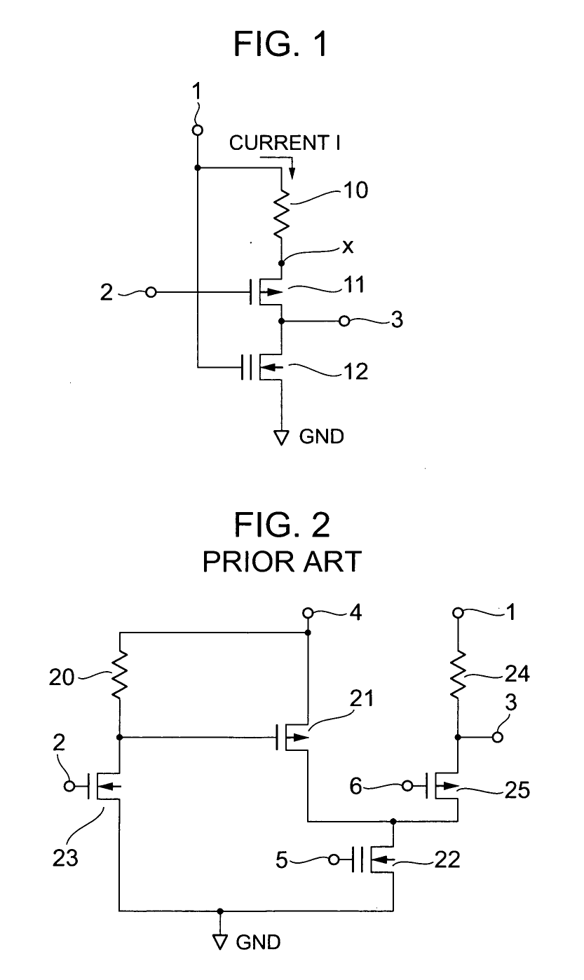

FIG. 1 shows an EPROM read/write circuit according to the present invention. A resistor 10, a PMOS transistor 11, and an EPROM 12 are connected one another in series between a power source voltage terminal 1 and a GND terminal. A gate of the PMOS transistor 11 is connected to a write control terminal 2, and a gate of the EPROM 12 is connected to the power source voltage terminal 1.

In order to perform write to the EPROM 12, the optimum voltage difference for the write is required between the gate terminal of the EPROM 12 and a drain terminal thereof. Therefore, a voltage Vw most suitable for the write in terms of characteristics of the EPROM 12 is applied to the power source voltage terminal 1.

Further, a current I[A] flows between a source and a drain of the EPROM 12 when the PMOS transistor 11 is in a conductive state. The resistor 10 sets the best voltage value at which a carrier is injected to a floating gate of the EPROM 12. When a resistance value of the resistor 10 is represented by Rw[Ω], a voltage Vrw generated at the resistor 10 can be obtained through Expression 1.
Vrw=I*Rw (Expression 1)

A voltage Vx of a node X is applied to the drain terminal of the EPROM 12 in the case of the PMOS transistor 11 being conductive, thereby becoming an EPROM write voltage. The voltage Vx of the node X can be obtained through Expression 2 with the voltage Vrw obtained through Expression 1 and the voltage Vw of the power source voltage terminal 1.
Vx=Vw−Vrw (Expression 2)

In order to perform the write to the EPROM, the optimum voltage Vw for the write is applied to the gate terminal of the EPROM 12, and the voltage Vx of the node X, which is obtained by the above-mentioned means, is applied to the drain terminal. Further, a write command signal input from the write control terminal 2 sets the PMOS transistor 11 in the conductive state. At this point, the PMOS transistor 11 is designed to operate in a non-saturation region with a small on resistance.

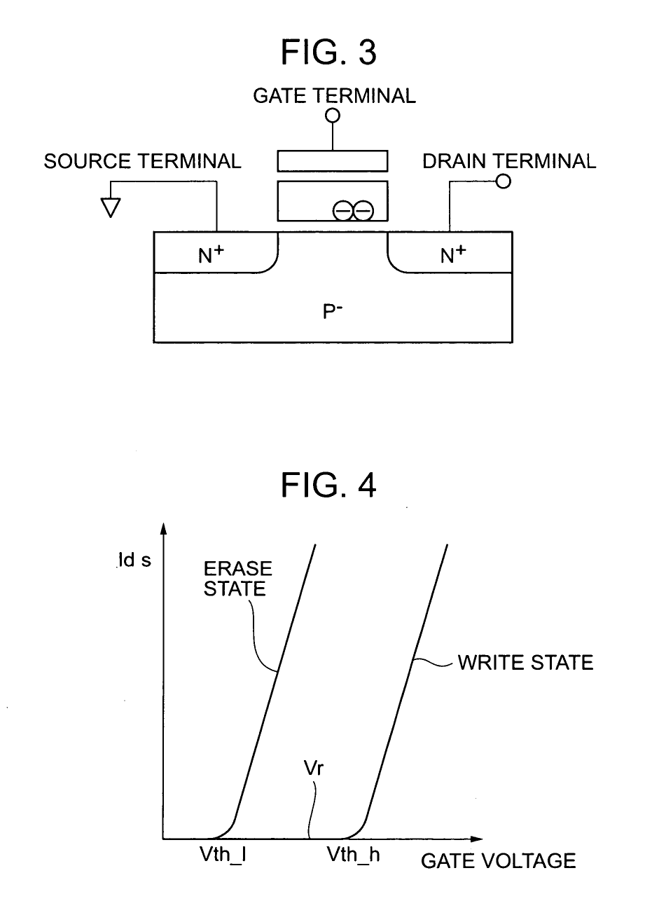

FIG. 3 is a structural view of a section of an EPROM. When the current I [A] flows between the source and the drain of the EPROM 12, electrons, which flow from the source region of the EPROM 12, become electrons with high energy in a high electric field region formed in the vicinity of the drain region of the EPROM 12. The electrons cause impact ionization with a silicon lattice in the vicinity, whereby electron hole pairs are generated. Because the high potential has been applied to the gate terminal of the EPROM 12, the electrons generated in the vicinity of the drain region of the EPROM 12 are injected to the floating gate. Since the floating gate is isolated from the periphery, the injected electrons are isolated. When the electrons are injected, the threshold voltage rises, and then, the EPROM 12 is brought into a write state. On the other hand, in the case where the PMOS transistor 11 is non-conductive due to the write command signal input from the write control terminal 2, the current does not flow between the source and the drain of the EPROM 12, and the carrier is not injected to the floating gate. Thus, the threshold voltage remains at an initial value, which leads to an erase state. Based on the above, the threshold voltage in the write state is represented by Vth_h, and the threshold voltage in the erase state is represented by Vth_l.

FIG. 4 is a diagram of a threshold voltage and a read voltage of the EPROM. For the read from the EPROM 12, the PMOS transistor 11 is set in the conductive state. As regards a gate terminal voltage Vr of the EPROM 12 at the time of read, that is, the read voltage, the optimum voltage value is set in a range from the threshold voltage Vth_l in the erase state to the threshold voltage Vth_h in the write state (Vth_l<Vr<Vth_h). That is, the voltage of the power source voltage terminal 1 at the time of read from the EPROM 12 is Vr. When the EPROM 12 is in the write state, the gate terminal voltage of the EPROM 12 is lower than the threshold voltage Vth_h. Thus, the output voltage terminal 3 is at a high potential. On the other hand, when the EPROM 12 is in the erase state, the gate terminal voltage of the EPROM 12 is higher than the threshold voltage Vth_l. Thus, the output voltage terminal 3 is at a low potential.

As described above, the EPROM read/write circuit of the present invention does not require two terminals, which are write voltage terminals, differently from a conventional EPROM read/write circuit. Accordingly, the costs can be reduced by holding down the chip size and the number of terminals.

### Embodiment 2

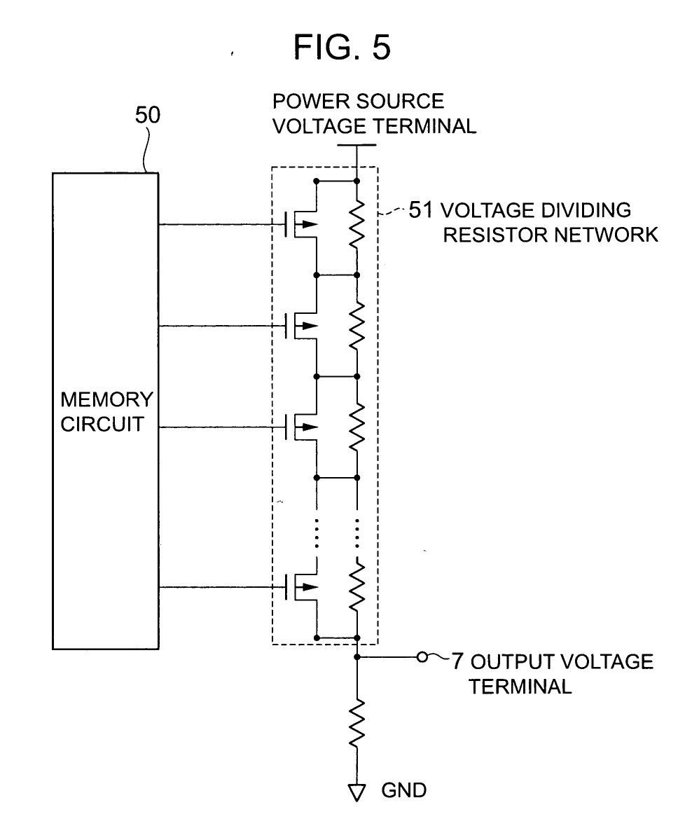

FIG. 5 is a circuit diagram in which the EPROM read/write circuit of the present invention is applied to a trimming circuit. The trimming circuit in FIG. 5 is constituted by a memory circuit 50 and a voltage dividing resistor network 51. The voltage dividing resistor network 51 is constituted by resistors and MOS switches connected to both ends of each of the resistors. The memory circuit 50 is a circuit including the EPROM read/write circuits as in FIG. 1 the number of which corresponds to the number of the resistors that constitute the voltage dividing resistor network 51. A gate terminal of each of the MOS switches is connected to the output voltage terminal 3 in the EPROM read/write circuit in FIG. 1. The power source voltage terminal is applied with the voltage Vr that has the same potential as that at the time of read of the EPROM.

The data output from the memory circuit in correspondence with a stored state of the EPROM is given to the gate of each of the MOS switches, whereby on/off control of the MOS switches is performed to set a resistance value of the voltage dividing resistor network.

From the above, in this embodiment, description has been made on the operation of the EPROM read/write circuit which uses the EPROM. However, other EPROMs such as an EEPROM can be also used.

1. A non-volatile memory circuit, which is electrically writable and uses an EPROM, comprising:
a resistor connected to a power source terminal;
a control transistor that connects the resistor to a source thereof and connects a control terminal to a gate thereof; and
an EPROM that connects a drain of the control transistor to a drain thereof and connects the power source terminal to a gate thereof,
wherein a connecting point of the drain of the control transistor and the drain of the EPROM is an output terminal.

2. A non-volatile memory circuit according to claim 1, wherein:
a signal is input to the control terminal to turn the control transistor on, and a write voltage- is applied to the power source terminal to perform write operation of the EPROM at the time of write; and
a signal is input to the control terminal to turn the control transistor on, and a read voltage is applied to the power source terminal to output information written in the EPROM to the output terminal at the time of read.

3. Anon-volatile memory circuit according to claim 1, wherein the control transistor is operated in a non-saturation region at the time of write.

4. Anon-volatile memory circuit according to claim 1, wherein the resistor also serves as a load resistor at the time of read.

5. A semiconductor device, comprising a trimming means comprised of an electrically writable non-volatile memory, wherein:
plural resistors are connected one another in series in the trimming means;
switching transistors are connected in parallel to both ends of each of the resistors; and
each of the switching transistors is controlled by the non-volatile memory circuit as claimed in claim 1.
